(19) United States
(12) Patent Application Publication
(10) Pub. No.: US 2011/0133607 A1
(43) Pub. Date: Jun. 9, 2011

(54) POLYMER ACTUATOR CONTAINING GRAPHENE AND METHOD OF PREPARING THE SAME

(75) Inventors: Hyung Kun LEE, Daejeon (KR); Nak Jin Choi, Daejeon (KR); Kwang Suk Yang, Daejeon (KR); Sun Kyung Jung, Daejeon (KR); Kang Ho Park, Daejeon (KR); Jong Dae Kim, Daejeon (KR)

(73) Assignee: Electronics and Telecommunications Research Institute, Daejeon (KR)

(21) Appl. No.: 12/861,726

(22) Filed: Aug. 23, 2010

(30) Foreign Application Priority Data
Dec. 3, 2009 (KR) 10-2009-0118872

(51) Int. Cl. H01L 41/193; H01L 41/26

(52) U.S. Cl. 310/365; 29/25.35

(57) ABSTRACT

A polymer actuator containing graphene and a method of preparing the same are provided. The polymer actuator includes an ion-conductive polymer membrane, a metal electrode disposed on both surfaces of the ion-conductive polymer membrane, and graphene dispersed within the ion-conductive polymer membrane. As the graphene is dispersed within the polymer membrane, reverse ion migration due to an osmotic pressure occurring after solvent migration caused by electrostimulation in operation of the actuator can be prevented, and thus drivability of the polymer actuator can be improved.

### CROSS-REFERENCE TO RELATED APPLICATION

This application claims priority to and the benefit of Korean Patent Application No. 10-2009-0118872, filed Dec. 3, 2009, the disclosure of which is incorporated herein by reference in its entirety.

### BACKGROUND

The present invention relates to a polymer actuator containing graphene and a method of preparing the same. More specifically, the present invention relates to a polymer actuator in which graphene is dispersed within an ion-conductive polymer to prevent reverse ion migration from occurring after solvent migration caused by electrostimulation, and a method of fabricating the same.

### DISCUSSION OF RELATED ART

An Ionic Polymer Metal Composite (IPMC) consists of a fluorinated ionic polymer membrane such as a Nafion™ membrane and a conductive metal, wherein both surfaces of the Nafion™ membrane are electroplated with metal electrodes.

When cations in the membrane are migrated by applying an electric field to the metal electrodes, the membrane is swollen and bent in the opposite direction to the migration of the cations, which results in the deformation of the membrane in the electrical field due to the membrane characteristics. Such deformation can be adjusted according to cations which are electrolytes present in the IPMC, a solvent (e.g., water, polar solvent or ionic liquid) delivering the cations, a voltage applied to the electrodes disposed on both surfaces of the membrane, or a frequency.

Recently, it has been reported that carbon nanotubes (CNTs) can be included in the ion-conductive polymer membrane to fabricate the IPMC. Some papers have reported that when 0 wt % to 7 wt % multiwalled CNTs (MWCNTs) were included in the ion-conductive polymer membrane to fabricate the IPMC, the drivability of the IPMC was significantly increased in the case of the IPMC including the MWCNTs with a content of 1 wt %.

However, in order to disperse the MWCNTs, an additional surfactant should be added and several pre-treatments should be performed, which makes it difficult to fabricate the IPMC effectively.

A paper also reported that montmorillonites (MMTs) were dispersed in the ion-conductive polymer membrane as a silica plate-shaped material to fabricate the IPMC. In addition, another paper reported that the MMTs were dispersed as the silica plate-shaped material to fabricate the IPMC and physical properties thereof were analyzed to find significantly enhanced drivability. However, there is actually an application limit due to a significant decrease in displacement among drivability characteristics.

Recently, research on graphene as the plate-shaped carbon material has been actively conducted, and a paper has reported that the graphene oxide can be easily reduced to the graphene, and its reduction is conducted by the reaction formula shown in FIG. 1.

As shown in FIG. 1, it was reported that the electric conductivity was increased about 10⁵ times by reducing the graphene oxide to the graphene. However, it is difficult to directly apply the reduction of the graphene oxide at the presence of the ion-conductive polymer membrane because of the possible damage of the polymer membrane requiring high temperature and strong sulfuric acid.

To cope with the problems described above, the present inventors have conducted research on the problems of the related art and found that the polymer actuator could be fabricated using the graphene as a plate-shaped carbon material to increase the drivability and utilizing a conductive property of the graphene to improve the displacement and drivability characteristics, thereby completing the present invention.

### SUMMARY OF THE INVENTION

The present invention is directed to a polymer actuator that can reveal a superior driving characteristic using graphene as a plate-shaped carbon material.

The present invention is also directed to a method of fabricating a polymer actuator that can reveal a superior driving characteristic using graphene as a plate-shaped carbon material.

One aspect of the present invention provides a polymer actuator including an ion-conductive polymer membrane, a metal electrode disposed on both surfaces of the ion-conductive polymer membrane, and graphene dispersed within the ion-conductive polymer membrane.

In the polymer actuator according to the present invention, the ion-conductive polymer membrane may be a Nafion™ polymer membrane, and the metal electrode may contain platinum or gold and have a thickness of 5 μm to 10 μm.

In addition, according to the polymer actuator of the present invention, 0.1 wt % to 10 wt % of the graphene with respect to the total weight of the ion-conductive polymer membrane may be dispersed within the ion-conductive polymer membrane.

Another aspect of the present invention provides a method of fabricating a polymer actuator comprising: dispersing a graphene oxide within an ion-conductive polymer solution; drying the dispersed solution to form an ion-conductive polymer membrane; and forming metal electrodes on both surfaces of the ion-conductive polymer membrane to form an ion-conductive polymer metal composite. Here, the method further comprises reducing the graphene oxide after dispersing the graphene oxide, drying the dispersed solution, or forming the metal electrodes.

In the method of fabricating the polymer actuator according to the present invention, the ion-conductive polymer solution may be a Nafion™ solution, and 0.1 wt % to 10 wt % of the graphene oxide may be dispersed with respect to the total weight of the ion-conductive polymer membrane.

In addition, in the method of fabricating the polymer actuator according to the present invention, drying the dispersed solution may be performed for one to twelve hours at 50° C. to 80° C., and the metal electrodes may be formed of platinum or gold with a thickness of 5 μm to 10 μm by electroplating.

In the method of fabricating the polymer actuator according to the present invention, the reduction may be performed with a chemical treatment using NH₂NH₂ and then heat-treated at 200° C. to 220° C.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a view illustrating a reaction formula in which a graphene oxide is reduced to graphene;

FIG. 2 is a perspective view of a polymer actuator where graphene is dispersed in accordance with an exemplary embodiment of the present invention;

FIG. 3 is a flow chart of illustrating a process of fabricating a polymer actuator where graphene is dispersed in accordance with an exemplary embodiment of the present invention;

FIG. 4 is a view illustrating a thermogravimetric analysis result of a graphene oxide; and

FIG. 5 is a view illustrating displacement and drivability characteristics of a polymer actuator where graphene evaluated in an exemplary test example of the present invention is dispersed.

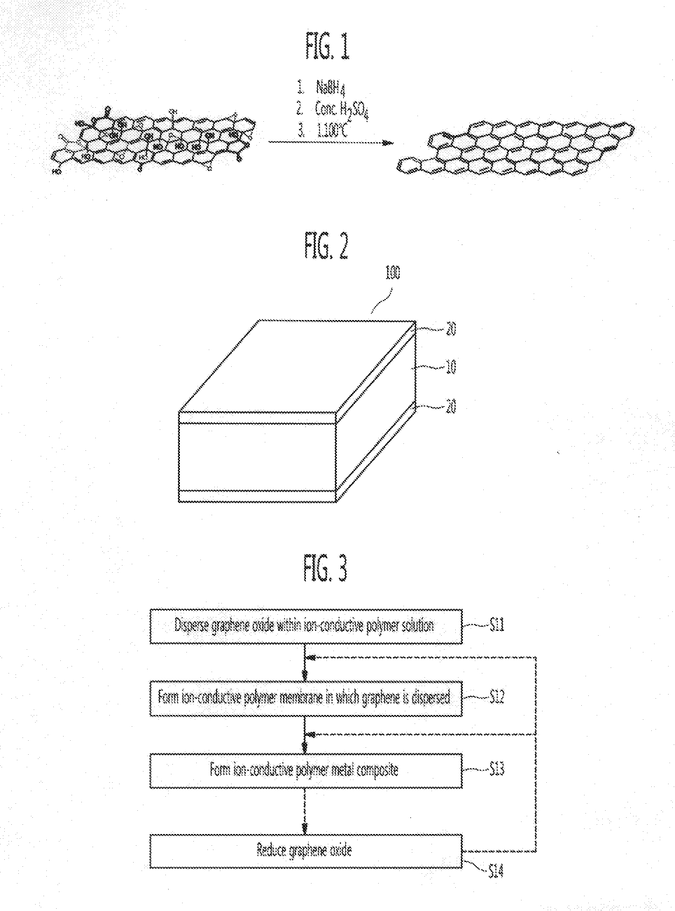

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein.

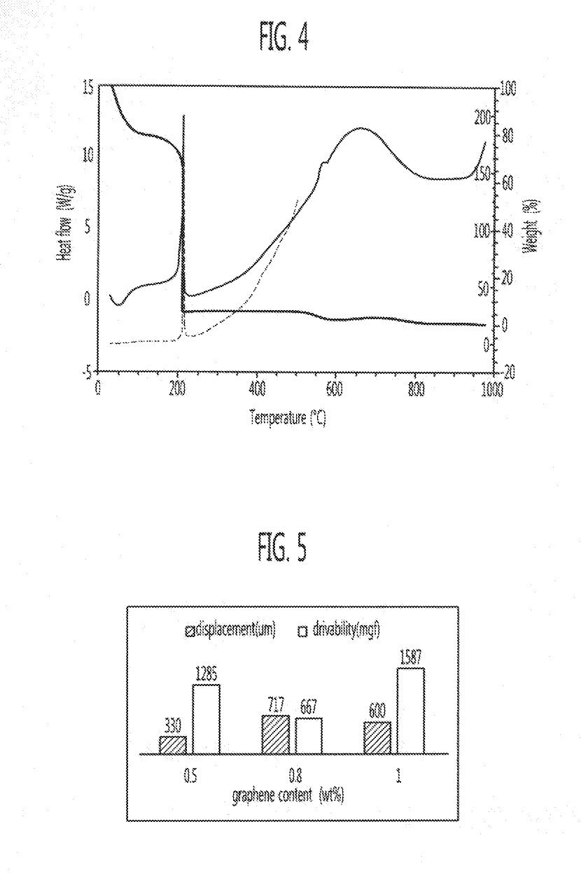

FIG. 2 is a perspective view of a polymer actuator where graphene is dispersed in accordance with an exemplary embodiment of the present invention, and FIG. 3 is a flow chart of illustrating a process of fabricating a polymer actuator where graphene is dispersed in accordance with an exemplary embodiment of the present invention.

Referring to FIG. 2, a polymer actuator 100 according to the present invention includes an ion-conductive polymer membrane 10, metal electrodes 20 disposed on both surfaces of the ion-conductive polymer membrane, and graphene (not shown) dispersed within the ion-conductive polymer membrane.

As shown in FIG. 3, the polymer actuator having the structure described above is fabricated by a method including dispersing a graphene oxide within an ion-conductive polymer solution (S11); drying the dispersed solution to form an ion-conductive polymer membrane (S12); and forming metal electrodes on both surfaces of the ion-conductive polymer membrane to form an ion-conductive polymer metal composite (S13), and the method further comprises reducing the graphene oxide (S14) after operation S11, operation S12, or operation S13.

A polymer actuator and a method of preparing the same will be described in detail with reference to FIGS. 2 and 3.

In operation S11 of dispersing the graphene oxide within the ion-conductive polymer solution, any ion-conductive polymer generally used in the art may be employed as the ion-conductive polymer, and preferably Nafion™. A general organic solvent known in the art may be employed as the solvent in which the ion-conductive polymer is dissolved.

0.1 wt % to 10 wt % of the dispersed graphene oxide is preferably contained in the ion-conductive polymer solution based on the weight of the ion-conductive polymer. When the weight of the graphene is less than 0.1 wt %, the electric conductivity and the mechanical properties are not enhanced, and when the weight of the graphene is greater than 10 wt %, the physical properties such as the electric conductivity may be enhanced, however, a problem may occur on formation of a uniform composite membrane.

In operation S12 of drying the dispersed solution to form the ion-conductive polymer membrane, the dispersed solution is dried for one to twelve hours at 50° C. to 80° C. to form the ion-conductive polymer membrane. The drying temperature and time may be changed depending on the solvent to be used.

In addition, in operation S13 of forming the metal electrodes on both surfaces of the ion-conductive polymer membrane to form the ion-conductive polymer metal composite, any metal known in the art may be used as the metal electrode, preferably platinum or gold, and a thickness of the metal electrode may be selected in a common range known in the art, preferably 5 to 10 μm. The metal electrode is preferably formed by an electroplating method.

The electroplating method of plating both surfaces of the polymer membrane with the metal electrode in order to obtain a bending phenomenon from the ion-conductive polymer membrane by the electric device has been employed from the method used in the Oguro group (see K. Oguro, http://ndeaa.jp1.nasa.gov/nasa-nde/lommas/eap/IPMC.htm).

Next, operation S14 of reducing the graphene oxide is carried out, and the graphene oxide may be reduced to the graphene by various reduction methods, one example whereof is to use NH₂NH₂ to be chemically treated and then thermally treated within 30 minutes at 200° C. to 220° C. In this case, the chemical treatment using NH₂NH₂ may be performed by heating for two to five hours at 60° C. to 100° C. in the NH₂NH₂ aqueous solution. Operation S14 of reducing the graphene oxide may be performed after operation S11, operation S12, or operation S13.

Hereinafter, the present invention will be described with reference to exemplary embodiments in detail to be more easily understood to those skilled in the art.

### Exemplary Embodiment 1

1 wt % of a graphene oxide aqueous solution was mixed with the organic solution in which 20 wt % Nafion was dissolved such that 0.5 wt % of the graphene oxide was present with respect to the weight of the Nafion, thereby preparing the graphene oxide/Nafion mixed solution.

Fabrication of the Ion-Conductive Polymer Membrane by Drying the Mixed Solution

6 ml of the mixed solution was put into the Teflon™ container and dried at 60° C. for 2 hours in an electric oven purged with nitrogen gas, thereby forming the Nafion membrane in which the graphene oxide is dispersed.

Fabrication of the Ionic Polymer Metal Composite

To increase a surface area of the Nafion membrane, the surface of the membrane was sandblasted using an oxygen plasma treatment. The sandblasting was performed at a rate of about 1 second per area (cm²). 2 mg per ml of a platinum complex ([Pt(NH₃)₄]Cl₂) solution was then prepared, and the membrane was immersed in a solution containing 3 mg or more Pt per membrane area (cm²). For example, at least 45 ml Pt solution was needed for the membrane having an area of 30 cm². After that, a 1 ml ammonium hydroxide solution (5%) was added for neutralization. The membrane was immersed overnight at a room temperature. The membrane having the area of 30 cm² was cleaned with water and put into a 180 ml stirring water in a water tank at 40° C., and a 2 ml sodium borohydride solution (5 wt % NaBH₄ aq) was added seven times every 30 minutes to the stirring water. The amount of the sodium borohydride solution should be proportional to the area of the membrane. Subsequently, the temperature was gradually increased to 60° C., a 20 ml reducing agent (NaBH₄) was added, and the mixture was stirred at 60° C. for one and a half hours. A black layer of the fine Pt particles was adsorbed on the surface of the membrane, thereby forming the metal electrode.

Reduction of Graphene Oxide

After the graphene oxide dispersed within the polymer of the ion-conductive polymer composite was heated in a NH₂NH₂ aqueous solution (1 wt %) at 80° C. for 3 hours, thermal treatment was performed at 200° C. to 220° C. for 15 minutes according to the thermogravimetric analysis shown in FIG. 4, thereby preparing the polymer actuator.

### Exemplary Embodiment 2

The polymer actuator was fabricated in the same manner as exemplary embodiment 1, except that the graphene oxide/Nafion mixed solution was prepared such that 0.8 wt % of the graphene oxide was present with respect to the weight of the Nafion.

### Exemplary Embodiment 3

The polymer actuator was fabricated in the same manner as exemplary embodiment 1, except that the graphene oxide/Nafion mixed solution was prepared such that 1.0 wt % of the graphene oxide was present with respect to the weight of the Nafion.

### Test Example

### Measurement of Displacement and Drivability

Measurement results of displacement and drivability of the polymer actuator having the graphene formed by exemplary embodiments 1 to 3 are shown in table 1 below and FIG. 5. The displacement was measured when a voltage (3 V, 0.1 Hz) was applied to the polymer actuator formed in a strip shape having a size of 3×8 mm² using a frequency generator.

TABLE 1

| | Exemplary | Exemplary | Exemplary |
|---|---|---|---|
| | Embodiment 1 | Embodiment 2 | Embodiment 3 |
| Displacement (μm) | 330 | 717 | 600 |
| Drivability (mgf) | 1285 | 667 | 1587 |

As can be seen from table 1, it was confirmed that since the graphene was contained, the displacement and drivability of the polymer actuator were increased.

According to the present invention, graphene is dispersed within an ion-conductive polymer membrane of a polymer actuator, reverse ion migration due to an osmotic pressure occurring after solvent migration caused by electrostimulation in operation of the actuator can be reduced, and thus drivability of the polymer actuator can be improved.

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A polymer actuator comprising:
an ion-conductive polymer membrane;
a metal electrode disposed on both surfaces of the ion-conductive polymer membrane; and
graphene dispersed within the ion-conductive polymer membrane.

2. The polymer actuator of claim 1, wherein the ion-conductive polymer membrane is a Nafion™ polymer membrane.

3. The polymer actuator of claim 1, wherein 0.1 wt % to 10 wt % of the graphene with respect to the total weight of the ion-conductive polymer membrane is dispersed within the ion-conductive polymer membrane.

4. A method of preparing a polymer actuator, comprising:
(S1) dispersing a graphene oxide within an ion-conductive polymer solution;
(S2) drying the dispersed solution to form an ion-conductive polymer membrane; and
(S3) forming metal electrodes on both surfaces of the ion-conductive polymer membrane to form an ion-conductive polymer metal composite,
wherein the method further comprises reducing the graphene oxide after operation S1, operation S2, or operation S3.

5. The method of claim 4, wherein the ion-conductive polymer solution is a Nafion™ solution.

6. The method of claim 4, wherein 0.1 wt % to 10 wt % of the graphene oxide is dispersed with respect to the total weight of the ion-conductive polymer membrane.

7. The method of claim 4, wherein drying the dispersed solution is performed for one to twelve hours at 50° C. to 80° C.

8. The method of claim 4, wherein the metal electrodes are formed of platinum or gold with a thickness of 5 μm to 10 μm by electroplating.

9. The method of claim 4, wherein reducing the graphene oxide is performed with a chemical treatment using NH₂NH₂ and then heat-treated at 200° C. to 220° C.
